(19) United States
(12) Patent Application Publication
(10) Pub. No.: US 2005/0219049 A1
(43) Pub. Date: Oct. 6, 2005

(54) Ethernet power supply structure

(76) Inventor: Chang-Liang Lin, Kuishan Hsiang (TW)

Correspondence Address: BRUCE H. TROXELL, SUITE 1404, 5205 LEESBURG PIKE, FALLS CHURCH, VA, 22041, US

(21) Appl. No.: 10/923,042

(22) Filed: Aug. 23, 2004

(30) Foreign Application Priority Data
Mar. 31, 2004 (TW) 93204946

(51) Int. Cl. H03K 5/159

(52) U.S. Cl. 340/538

(57) ABSTRACT

An Ethernet power supply structure including a power module, a network power supply controlling module and a power/signal combination module. Via the network power supply controlling module, the power module provides necessary power for the power/signal combination module. The power module also directly provides necessary power for an external signal source such as a hub and inputs the data signal of the external signal source into the power/signal combination module. The power/signal combination module combines the data signal input by the external signal source with the power transmitted by the power module into a data signal associated with the power. Via the Ethernet line, the power and data signal can be simultaneously transmitted to a preset external unit such as a wireless base station.

### BACKGROUND OF THE INVENTION

The present invention is related to an improved Ethernet power supply structure, and more particularly to a power supply which via an Ethernet line can simultaneously transmit power and data signal meeting 802.3af-2003 Protocol regulated by IEEE.

There are more and more computer peripheral equipments which utilize Ethernet as data transmission interface. However, the conventional Ethernet line simply serves to transmit data signal. Therefore, all the above computer peripheral equipments utilizing Ethernet as data transmission interface are powered by independent power supply. Accordingly, the use of the computer peripheral equipments is limited by the location of the power supply. As a result, the layout of the computer peripheral equipments is quite restricted. In a place lacking any power, it will be impossible to use the computer peripheral equipments utilizing the Ethernet cannot. Moreover, the computer peripheral equipments necessitate independent exclusive power structure. This leads to increment of manufacturing cost. In order to solve the above problems, IEEE regulated 802.3af-2003 Protocol in 2003 to regulate the application technique utilizing the Ethernet cable for transmitting power and data signal at the same time. Accordingly, the peripheral equipments at the terminal of the network line can be free from the restriction of power wire so that the use of the peripheral equipments is facilitated.

FIG. 1 is a block diagram of a power sourcing equipment (PSE) meeting the regulation of 802.3af-2003 Protocol. Such Ethernet power sourcing equipment 4 must have two independent adapters 411, 421. One adapter 411 serves to convert the AC power B and transmit necessary power via a power controller 41. The other adapter 421 serves to convert the AC power A and provide working power for a data source 42 such as a hub. A power/signal mixer 43 is used to combine the power of the power controller 41 and the output signal of the data source 42 and then output the data signal C associated with the power. Accordingly, via the Ethernet line, the power and data signal can be simultaneously transmitted.

However, the above power sourcing equipment 4 with two independent adapters 411, 421 is manufactured at higher cost and has large volume and complicated layout of system. Therefore, it is still needed to improve the Ethernet power supply structure.

### SUMMARY OF THE INVENTION

It is therefore a primary object of the present invention to provide an improved Ethernet power supply structure including one single power module, a network power supply controlling module and a power/signal combination module. The power module directly provides necessary power for an external signal source such as a hub and inputs the data signal of the external signal source into the power/signal combination module. Via the network power supply controlling module, the power module also provides necessary power for the power/signal combination module. The power/signal combination module combines the data signal input by the external signal source with the power transmitted by the power module into a data signal associated with the power. Via the Ethernet line, the power and data signal can be simultaneously transmitted to a preset external unit such as a wireless base station. The structure of the external unit can be simplified and the cost for the power supply is saved.

The present invention can be best understood through the following description and accompanying drawings wherein:

### BRIEF DESCRIPTION OF THE DRAWINGS

FIG. 1 is a block diagram of a conventional power sourcing equipment;

FIG. 2 is a block diagram of the power supply structure of the present invention;

FIG. 3 is a perspective view of an embodiment of the present invention, which has one set of network sockets; and

FIG. 4 is a perspective view of an embodiment of the present invention, which has two sets of network sockets.

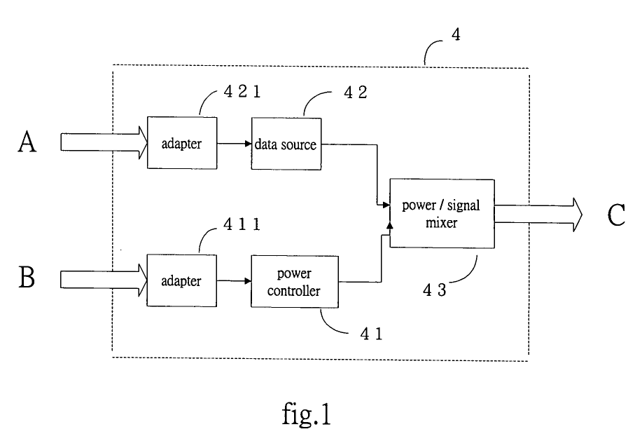

### DETAILED DESCRIPTION OF THE PREFERRED EMBODIMENTS

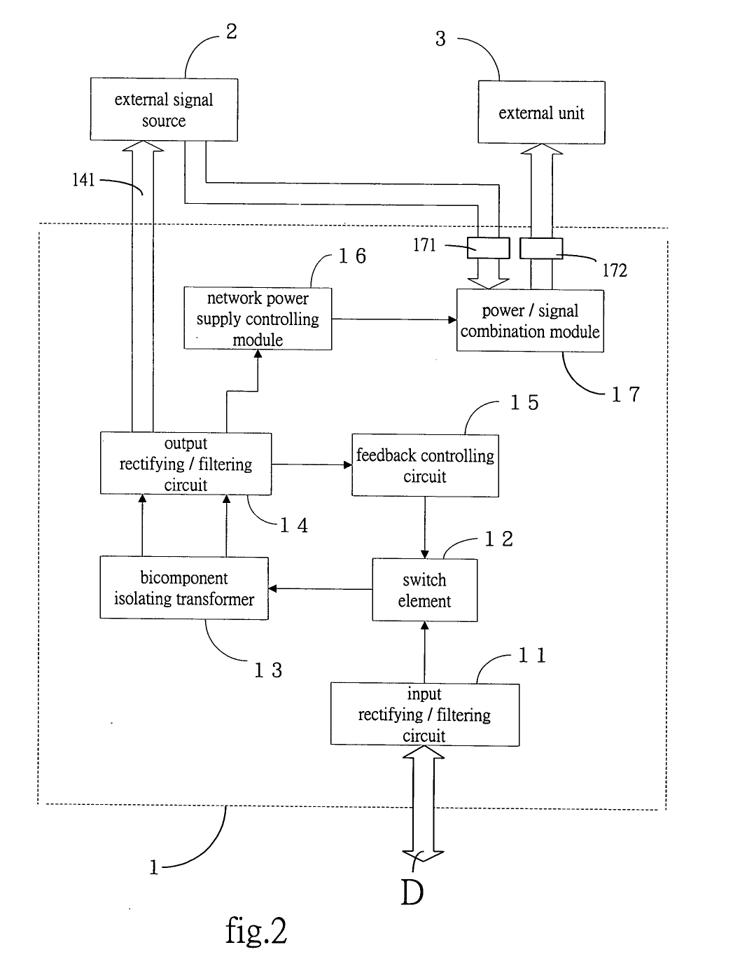

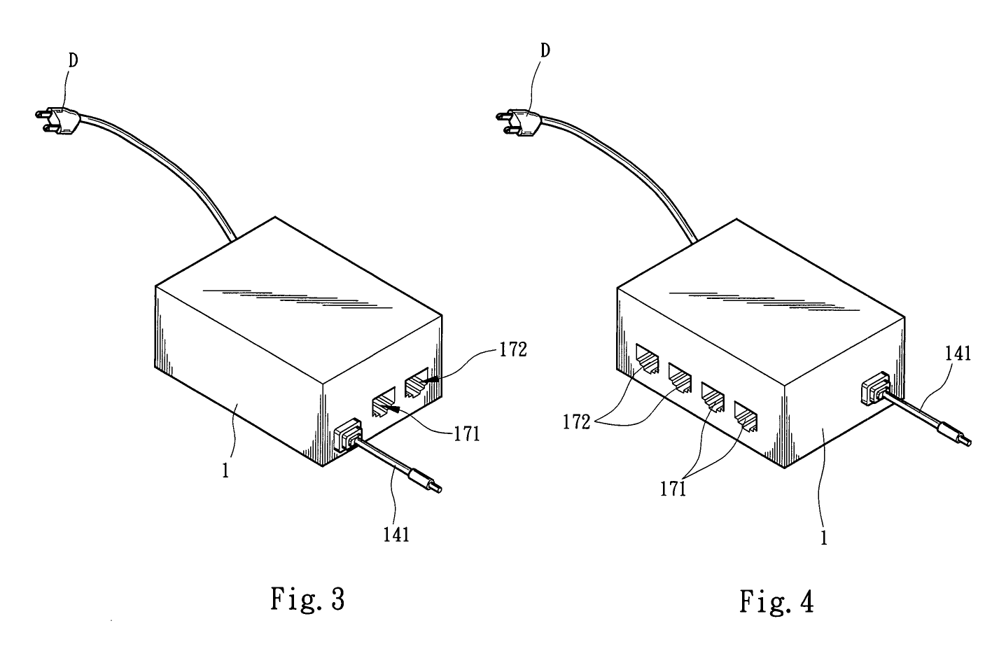

Please refer to FIG. 2. The power sourcing equipment 1 of the present invention includes an input rectifying/filtering circuit 11 connected to an external AC power port, a switch element 12, a bicomponent isolating transformer 13, an output rectifying/filtering circuit 14, a feedback controlling circuit 15, a network power supply controlling module 16 and a power/signal combination module 17. The input rectifying/filtering circuit 11 via the switch element 12 is connected with the bicomponent isolating transformer 13. The bicomponent isolating transformer 13 is connected with the output rectifying/filtering circuit 14. The output rectifying/filtering circuit 14 is connected with an external signal source 2 (such as a hub, a switch, etc.), the network power supply controlling module 16 and the feedback controlling circuit 15. The feedback controlling circuit 15 is connected with the switch element 12. The network power supply controlling module 16 is connected with the power/signal combination module 17. The power/signal combination module 17 via a set of (at least one) Ethernet line sockets 172 as shown in FIGS. 3 and 4 is connected with an external unit 3.

The input rectifying/filtering circuit 11 serves to rectify/filter the external AC power into DC power which via the switch element 12 is output to the bicomponent isolating transformer 13. The bicomponent isolating transformer 13 converts the nominal power voltage into two necessary independent component voltage values. The two component voltages are further rectified/filtered by the output rectifying/filtering circuit 14. Thereafter, one component DC power 141 is directly provided for the external signal source 2. The other component DC power via the network power supply controlling module 16 is sent to the power/signal combination module 17. The power/signal combination module 17 can receive the network data signal of the external signal source 2 via another set of (at least one) Ethernet line sockets 171 as shown in FIGS. 3 and 4, whereby the network data signal is combined with the aforesaid DC power into a data signal associated with the power. The data signal via the Ethernet line is transmitted to the external unit 3 (low power consumption network utility such as a minitype radio base station, network camera, network phone, etc.). Accordingly, by means of the Ethernet line, the external unit 3 can obtain the power necessary for the operation and at the same time bidirectionally transmit data signal. The feedback controlling circuit 15 serves to monitor the output voltage of the rectifying/filtering circuit 14 to control the time during which the switch element 12 energizes the bicomponent isolating transformer 13 and the input rectifying/filtering circuit 11. Accordingly, the output can be increased in accordance with the change of load to achieve an optimal conversion efficiency.

In actual application, the external signal source 2 is a network data source, that is, generally a station equipped with a switch, hub or wideband network knot. In the case of an ordinary family or small-size office, the signal source 2 can be an ADSL modem. A network user must contact with outer side through this place. In general, the external unit 3 is a network utility with lower power consumption such as small-size wireless base station, network camera, network phone, etc. which necessitate the network for connection. These units have a commonness, that is, being positioned in a place without any power socket. By means of the present invention, the Ethernet line for transmitting data signal can at the same time transmit the power for the external unit 3. Accordingly, the layout of power wire can be omitted to facilitate use and reduce using cost.

According to the above arrangement, the Ethernet power supply structure of the present invention can simultaneously provide power necessary for the external data source and transmit the data signal.

The above embodiments are only used to illustrate the present invention, not intended to limit the scope thereof. Many modifications of the above embodiments can be made without departing from the spirit of the present invention.

1. An Ethernet power supply structure comprising:
a bicomponent isolating transformer for converting a nominal power voltage into two preset independent component voltages and outputting the two component voltages;
an output rectifying/filtering circuit for rectifying/filtering the two component voltages output by the bicomponent isolating transformer into DC powers, one of the component DC power being directly provided for an external signal source, while the other component DC power being transmitted to a power/signal combination module; and
at least one power/signal combination module, an input terminal of the power/signal combination module being connected with the external signal source and the output rectifying/filtering circuit for combining the transmitted data signal with the DC power into a data signal associated with the power, an output terminal of the power/signal combination module via an Ethernet line being connected with a preset external unit, whereby via the Ethernet line, the power can be provided for the external unit and at the same time the data signal can be transmitted to the external unit.

2. The Ethernet power supply structure as claimed in claim 1, wherein a network power supply controlling module is connected between the output rectifying/filtering circuit and the power/signal combination module for controlling the power supply of the output rectifying/filtering circuit for the power/signal combination module.

3. The Ethernet power supply structure as claimed in claim 1, wherein a switch element and an input rectifying/filtering circuit are disposed between the bicomponent isolating transformer and an AC power, the switch element being connected with a feedback controlling circuit for monitoring the output/rectifying/filtering circuit, whereby the input rectifying/filtering circuit rectifies/filters the AC power into DC power which via the switch element is output to the bicomponent isolating transformer, the feedback controlling circuit mnitoring the output voltage of the output rectifying/filtering circuit to control the time during which the switch element energizes the bicomponent isolating transformer and the input rectifying/filtering circuit, whereby the output can be increased in accordance with the change of load to achieve an optimal conversion efficiency.

4. The Ethernet power supply structure as claimed in claim 2, wherein a switch element and an input rectifying/filtering circuit are disposed between the bicomponent isolating transformer and an AC power, the switch element being connected with a feedback controlling circuit for monitoring the output/rectifying/filtering circuit, whereby the input rectifying/filtering circuit rectifies/filters the AC power into DC power which via the switch element is output to the bicomponent isolating transformer, the feedback controlling circuit mnitoring the output voltage of the output rectifying/filtering circuit to control the time during which the switch element energizes the bicomponent isolating transformer and the input rectifying/filtering circuit, whereby the output can be increased in accordance with the change of load to achieve an optimal conversion efficiency.

5. The Ethernet power supply structure as claimed in claim 1, wherein the power/signal combination module has one set of network sockets.

6. The Ethernet power supply structure as claimed in claim 2, wherein the power/signal combination module has one set of network sockets.

7. The Ethernet power supply structure as claimed in claim 3, wherein the power/signal combination module has one set of network sockets.

8. The Ethernet power supply structure as claimed in claim 4, wherein the power/signal combination module has one set of network sockets.

9. The Ethernet power supply structure as claimed in claim 1, wherein the power/signal combination module has at least two sets of network sockets.

10. The Ethernet power supply structure as claimed in claim 2, wherein the power/signal combination module has at least two sets of network sockets.

11. The Ethernet power supply structure as claimed in claim 3, wherein the power/signal combination module has at least two sets of network sockets.

12. The Ethernet power supply structure as claimed in claim 4, wherein the power/signal combination module has at least two sets of network sockets.
